(19) United States
(12) Patent Application Publication
(10) Pub. No.: US 2019/0242759 A1
(43) Pub. Date: Aug. 8, 2019

(54) THERMISTOR DRIVE CIRCUIT

(71) Applicant: DENSO CORPORATION, Kariya-city (JP)

(72) Inventor: Shogo HIKOSAKA, Kariya-city (JP)

(21) Appl. No.: 16/387,649

(22) Filed: Apr. 18, 2019

Related U.S. Application Data
(63) Continuation of application No. PCT/JP2017/030925, filed on Aug. 29, 2017.

(30) Foreign Application Priority Data
Nov. 9, 2016 (JP) 2016-218944

(51) Int. Cl. G01K 7/25; G01K 7/14; H03M 1/18; H03G 1/00

(52) U.S. Cl. CPC G01K 7/25; H03G 1/0041; H03M 1/18; G01K 7/14

(57) ABSTRACT

A thermistor drive circuit includes a plurality of driving resistors, at least one current correction resistor, a voltage measurement unit and a controller. The driving resistors are selectively connected to a thermistor for correcting a temperature characteristic of the thermistor whose resistance value changes in accordance with a temperature to be detected. The current correction resistor is selectively connected between a power supply and a ground. The voltage measurement unit measures a terminal voltage of the thermistor. The controller switches connection states of the driving resistors according to the terminal voltage. When switching the connection states of the driving resistors, the controller also switches a connection state of the current correction resistor to suppress a fluctuation of a power supply current before and after the switching of the connection states of the driving resistors.

### CROSS REFERENCE TO RELATED APPLICATIONS

The present application is a continuation application of International Patent Application No. PCT/JP2017/030925 filed on Aug. 29, 2017, which designated the U.S. and claims the benefit of priority from Japanese Patent Application No. 2016-218944 filed on Nov. 9, 2016. The entire disclosures of all of the above applications are incorporated herein by reference.

### TECHNICAL FIELD

The present disclosure relates to a thermistor drive circuit that drives a thermistor by applying a power supply current to the thermistor.

### BACKGROUND

When the temperature is detected by a thermistor, a driving resistor having a low temperature characteristic is connected in series to the thermistor to obtain an output which is obtained by dividing a power supply voltage. Generally, the thermistor has a poor linearity in a terminal across voltage, because the terminal across voltage changes exponentially according to the temperature being detected, and a range of the output voltage is widened.

### SUMMARY

### BRIEF DESCRIPTION OF DRAWINGS

The above and other objects, features and advantages of the present disclosure will become more apparent from the following detailed description made with reference to the accompanying drawings, in which:

FIG. 1 is a diagram illustrating a configuration of a thermistor drive circuit according to a first embodiment;

FIG. 2 is a diagram for explaining a state in which a measurement mode is switched according to a level of a temperature detected by a thermistor;

FIG. 3 is a diagram illustrating temperature characteristics of a thermistor resistance value;

FIG. 4 is a diagram illustrating a change of a power supply current accompanying switching of the measurement mode;

FIG. 5 is a diagram illustrating a change of an output voltage according to the temperature detected by the thermistor;

FIG. 6 is a diagram illustrating specific numerical examples of a driving resistor and a current correction resistor;

FIG. 7 is a diagram illustrating a configuration of a thermistor drive circuit according to a second embodiment;

FIG. 8 is a diagram for explaining a state in which a measurement mode is switched according to a level of a temperature detected by a thermistor;

FIG. 9 is a diagram illustrating a configuration of a thermistor drive circuit according to a third embodiment;

FIG. 10 is a diagram illustrating a configuration of a multiplexer incorporated in a voltage measurement unit;

FIG. 11 is a diagram for explaining an off leak current generated inside the multiplexer; and

FIG. 12 is a diagram illustrating a configuration of a thermistor drive circuit according to a fourth embodiment.

### DETAILED DESCRIPTION

For example, there have been known a technique of switching a driving resistor according to the temperature so as to improve the linearity or a technique of employing a configuration of limiting the range of the output voltage. In the technique of switching the driving resistor, however, since the amount of the power supply current is changed in accordance with the switching of the driving resistor, the power supply voltage is likely to be largely fluctuated with the change in the amount of the power supply current.

According to an aspect of the present disclosure, a thermistor drive circuit includes: a plurality of driving resistors configured to be selectively connected to a thermistor for correcting a temperature characteristic of the thermistor whose resistance value changes in accordance with a temperature to be detected; at least one current correction resistor configured to be selectively connected between a power supply and a ground; a voltage measurement unit configured to measure a terminal voltage of the thermistor; and a controller configured to switch connection states of the plurality of driving resistors according to the terminal voltage, and to switch a connection state of the at least one current correction resistor when switching the connection states of the plurality of driving resistors to suppress a fluctuation of a power supply current before and after the switching of the connection states of the plurality of driving resistors.

In the above configuration, when the controller switches the connection states of the driving resistors according to the terminal voltage of the thermistor, the controller also switches the connection state of the current correction resistor, so that the fluctuation in power supply current before and after the switching of the connection state of the driving resistors is suppressed. As such, the fluctuation of the power supply voltage can be suppressed.

For example, when the controller switches the connection states of the driving resistors to increase a resistance value, the controller may switch the connection state of the current correction resistor so as to reduce a resistance value.

Various embodiments of the present disclosure will be hereinafter described with reference to the drawings.

### First Embodiment

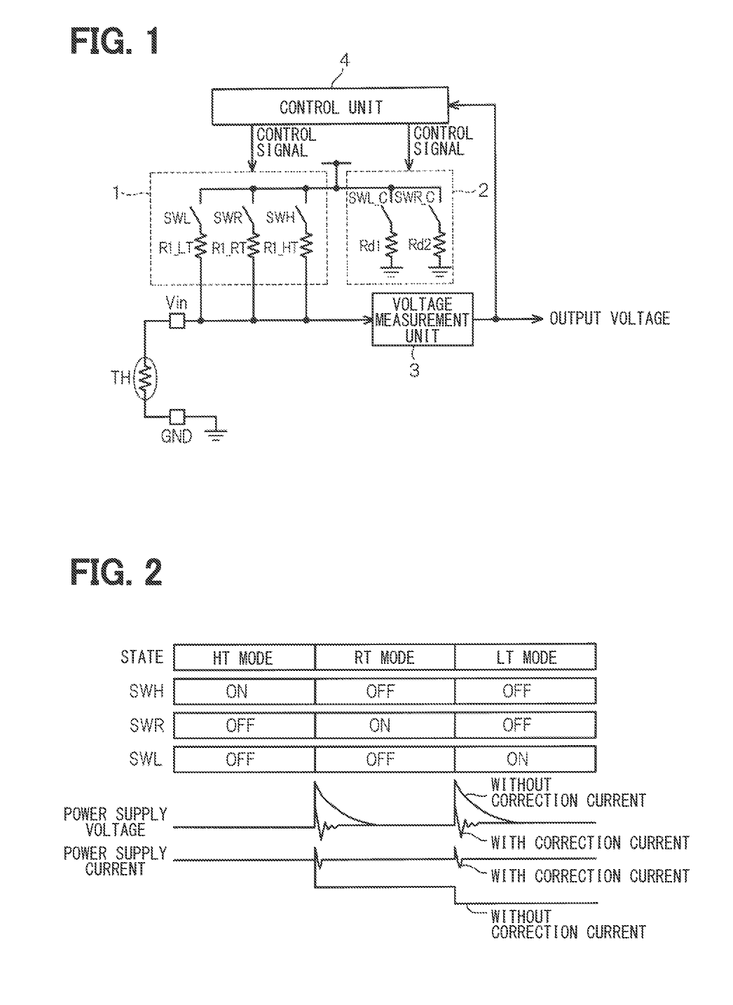

As shown in FIG. 1, a thermistor TH has a terminal GND connected to the ground. Three series circuits of switches SWL, SWR, and SWH and driving resistors R1_LT, R1_RT, and R1_HT, which are correspondingly connected, are connected in parallel between a power supply and a terminal Vin of the thermistor TH. These three series circuits constitute a linearity correction unit 1. Further, two series circuits of switches SWL_C and SWR_C and current correction resistors Rd1 and Rd2, which are correspondingly connected, are connected in parallel between the power supply and the ground. These two series circuits constitute a current correction unit 2.

The terminal Vin of the thermistor TH is connected to an input terminal of a voltage measurement unit 3. The voltage measurement unit 3 is, for example, an A/D converter, a sample-hold circuit, or the like. The voltage measurement unit 3 measures a terminal voltage of the thermistor TH, and outputs the measured terminal voltage to a control unit 4 as a controller and to an external device. The control unit 4 is provided by, for example, a microcomputer or hardware logic. The control unit 4 controls a connection state of each switch of the linearity correction unit 1 and the current correction unit 2 according to voltage data received from the voltage measurement unit 3.

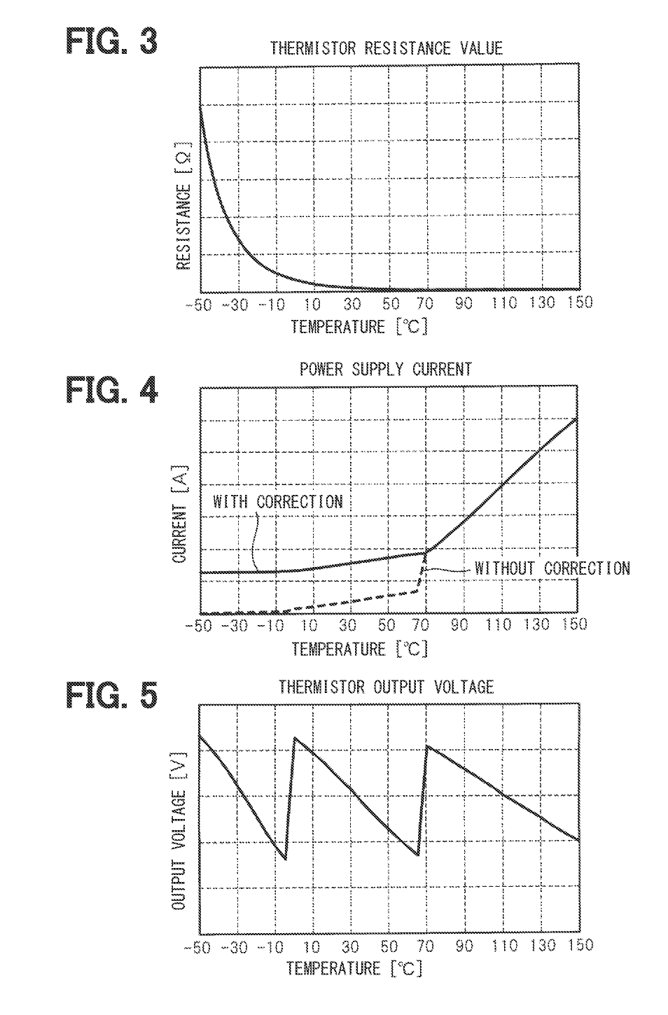

Next, an operation of the present embodiment will be described. As shown in FIG. 3, the resistance value of the thermistor TH has a negative temperature characteristic which decreases exponentially as the temperature to be detected rises. In order to improve the linearity of the output voltage based on the temperature characteristic, the control unit 4 selectively switches over the driving resistors R1_LT, R1_RT and R1_HT to be connected to the thermistor TH according to the range of the temperature detected by the thermistor TH. For example, the temperature range is divided into the following three temperature zones:
Low temperature zone LT: −5° C. (degrees Celsius) or lower
Intermediate temperature zone RT: higher than −5° C. and 60° C. or lower
High temperature zone HT: higher than 65° C.

In the low temperature zone LT, only the switch SWL is closed to connect the resistor R1_LT to the thermistor TH. In the intermediate temperature zone RT, only the switch SWR is closed to connect the resistor R1_RT to the thermistor TH. In the high temperature zone HT, only the switch SWH is closed to connect the resistor R1_HT to the thermistor TH.

When the resistors R1_LT, R1_RT, and R1_HT of the linearity correction unit 1 are switched in this way, as indicated by a broken line in FIG. 4, the amount of power supply current to be conducted to the thermistor TH largely fluctuates in accordance with the switching of the resistors R1_LT, R1_RT, and R1_HT, resulting in a large fluctuation of the power supply voltage. Therefore, in the present embodiment, the control unit 3 also switches the connection states of the current correction resistors Rd1 and Rd2 of the current correction unit 2 so as to suppress the amount of fluctuation of the power supply current due to the above switching of the connection states.

As shown in FIG. 2, in a HT mode, only the switch SWH is closed as described above. In an RT mode, the switch SWR is closed as well as the switch SWR_C of the current correction unit 2 is closed to connect the resistor Rd2 between the power supply and the ground. Thus, the fluctuation of the power supply current before and after the switching from the HT mode to the RT mode is suppressed. In an LT mode, the switch SWL is closed as well as the switch SWL_C of the current correction unit 2 is closed to connect the resistor Rd1 between the power supply and the ground. Thus, the fluctuation of the power supply current before and after the switching from the RT mode to the LT mode is similarly suppressed.

These operations are similarly performed when the detected temperature shifts from the low temperature zone LT toward the high temperature zone HT. Thus, the fluctuation of the power supply current before and after the switching from the LT mode to the RT mode and the switching from the RT mode to the HT mode is suppressed. That is, the opening and closing of the switch SWL_C is performed in the switching between the RT mode and the LT mode, and the opening and closing of the switch SWR_C is performed in the switching between the HT mode and the RT mode. Even if the connection states of the resistors Rd1 and Rd2 of the current correction unit 2 are switched in this manner, the terminal voltage of the thermistor TH is not particularly affected, as shown in FIG. 5.

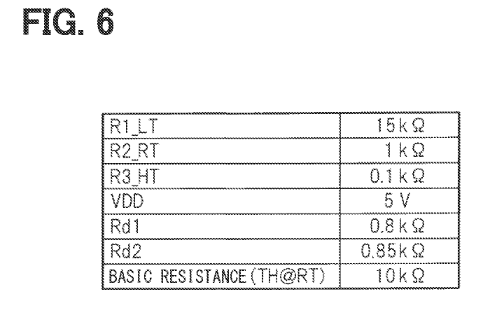

FIG. 6 shows a specific numerical example of each resistance value. In a case where the power supply voltage is 5V and the basic resistance of the thermistor TH in the RT mode is 10 kΩ, the resistance values of the driving resistors R1_LT, R1_RT and R1_HT and the current correction resistors Rd1 and Rd2 are set as follows: R1_LT=15 kΩ; R1_RT=1 kΩ; R1_HT=0.1 kΩ; Rd1=0.8 kΩ; Rd2=0.85 kΩ.

According to the present embodiment, as described above, it is configured that the current correction resistors Rd1 and Rd2 are selectively connected between the power supply and the ground. Further, when switching the connection states of the driving resistors R1_LT, R1_RT, and R1_HT so as to increase the resistance value according to the terminal voltage of the thermistor TH, the control unit 4 switches also the connection states of the current correction resistors Rd1 and Rd2 so as to reduce the resistance value, thereby suppressing the fluctuation of the power supply current before and after the switching of the plural driving resistors. As such, the fluctuation of the power supply voltage can also be suppressed.

### Second Embodiment

Hereinafter, the same parts as those in the first embodiment will be designated with the same reference numerals and descriptions thereof will be omitted. The following description will focus on different parts.

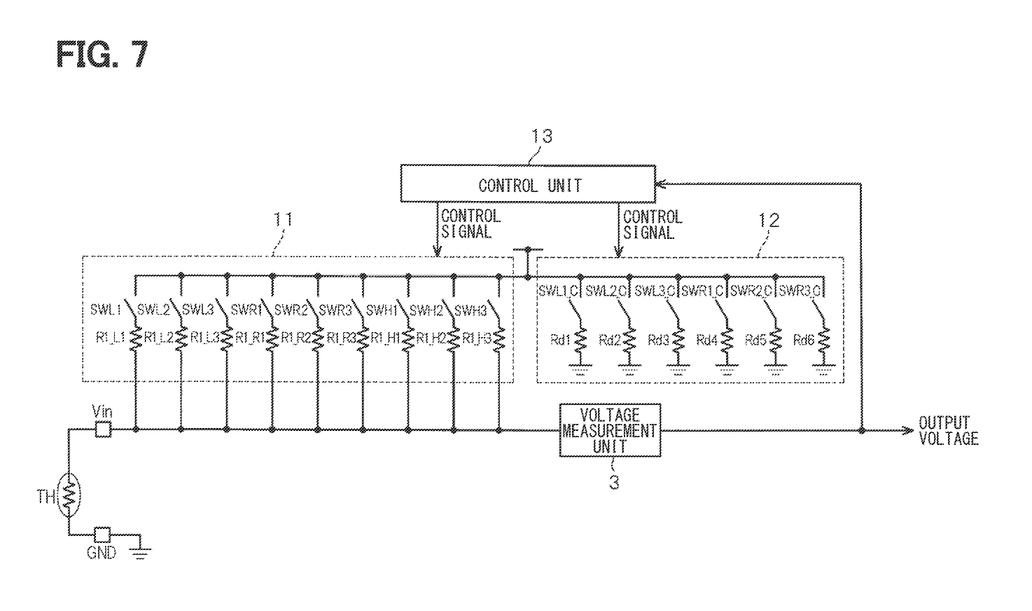

As shown in FIG. 7, in the second embodiment, the linearity correction unit 11 includes three sets of series circuits, each having a switch and a resistor, for each of the HT, RT and LT modes so to change the series resistance value between the power supply and the ground, as follows:
For HT mode switches SWH1 to SWH3 and resistors R1_H1 to R1_H3
For RT mode switches SWR1 to SWR3 and resistors R1_R1 to R1_R3
For LT mode: switches SWL1 to SWL3 and resistors R1_L1 to R1_L3

The parallel resistance values of the resistors R1_H1 to R1_H3, R1_R1 to R1_R3, and R1L1 to R1_L3 are, respectively, set equal to the resistance values of the resistors R1_HT, R1_RT, and R1_LT of the first embodiment.

Corresponding to the configuration of the linearity correction unit 11, the current correction unit 12 also has three sets of series circuits each having a switch and a resistor, to be used at the time of switching the mode between the HT mode and the RT mode and between the RT mode and the LT mode.

Namely, the switches SWR1_C to SWR3_C and the resistors Rd4 to Rd6 are provided for the switching between the HT mode and the RT mode; and the switches SWL1_C to SWL3 _C and resistors Rd1 to Rd3 are provided for the switching between the RT mode and the LT mode.

The parallel resistance values of the resistors Rd4 to Rd6 and the resistors Rd1 to Rd3 are respectively set equal to the resistance values of the resistors Rd2 and Rd1 of the first embodiment. The control unit 13 controls the switches of the linearity correction unit 11 and the current correction unit 12.

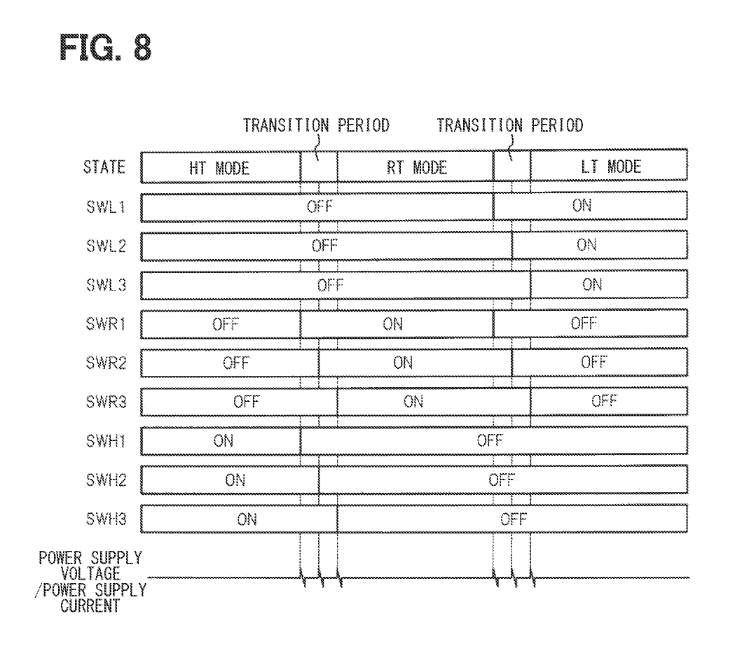

Next, operations of the second embodiment will be described. As shown in FIG. 8, the control unit 13 closes only the switches SWH1 to SWH3 in the HT mode. When shifting from the HT mode to the RT mode, that is, in the transition period from the HT mode to the RT mode shown in FIG. 8, the control unit 13 sequentially opens the switches SWH1, SWH2 and SWH3 as well as sequentially closes the switches SWR1, SWR2 and SWR3 corresponding to the timings of sequentially opening the switched SWH1, SWH2, and SWH3. In addition, the control unit 13 sequentially closes the switches SWR1_C, SWR2_C and SWR3_C corresponding to the timings of sequentially closing the switches SWR1, SWR2 and SWR3. Since the control unit 13 controls the switches of the linearity correction unit 11 and the current correction unit 12 in this manner, the fluctuation of the power supply current when shifting from the HT mode to the RT mode is further reduced, and the fluctuation of the power supply voltage is thus suppressed.

Similarly, when shifting from the RT mode to the LT mode, the control unit 13 sequentially opens the closed switches SWR1, SWR2, and SWR3 as well as sequentially closes the switches SWL1, SWL2, and SWL3 corresponding to the timing of sequentially opening the switches SWR1, SWR2, and SWR3. In addition, the control unit 13 sequentially closes the switches SWL1_C, SWL2_C, and SWL3_C corresponding to the timings of sequentially closing the switches SWL1, SWL2, and SWL3.

As described above, according to the second embodiment, the control unit 13 switches the connection states of the current correction resistors stepwise, when switching the measurement mode between the HT, RT, and LT modes. Accordingly, the fluctuation of the power supply current when shifting the measurement modes is further reduced, and the fluctuation of the power supply voltage is thus further suppressed.

### Third Embodiment

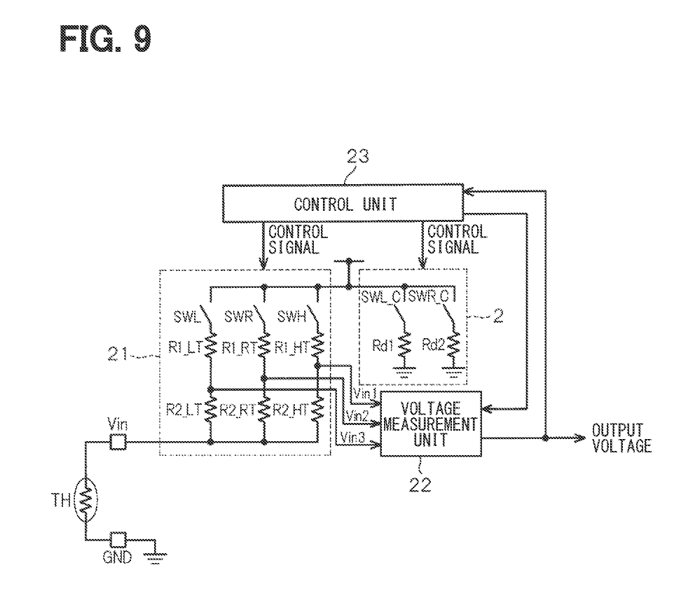

As shown in FIG. 9, in a third embodiment, a linearity correction unit 21 has level shifting resistors R2_LT, R2_RT and R2_HT, respectively, inserted between the resistors R1_LT, R1_RT and R1_HT and the upper terminal of the thermistor TH. A common connection point between the resistors R1_LT and R2_LT, a common connection point between the resistors R1_RT and R2_RT, and a common connection point between the resistors R1_HT and R2_HT are connected to corresponding input terminals of a voltage measurement unit 22. The voltages at the common connection points are referred to as voltages Vin3, Vin2, and Vin1, respectively.

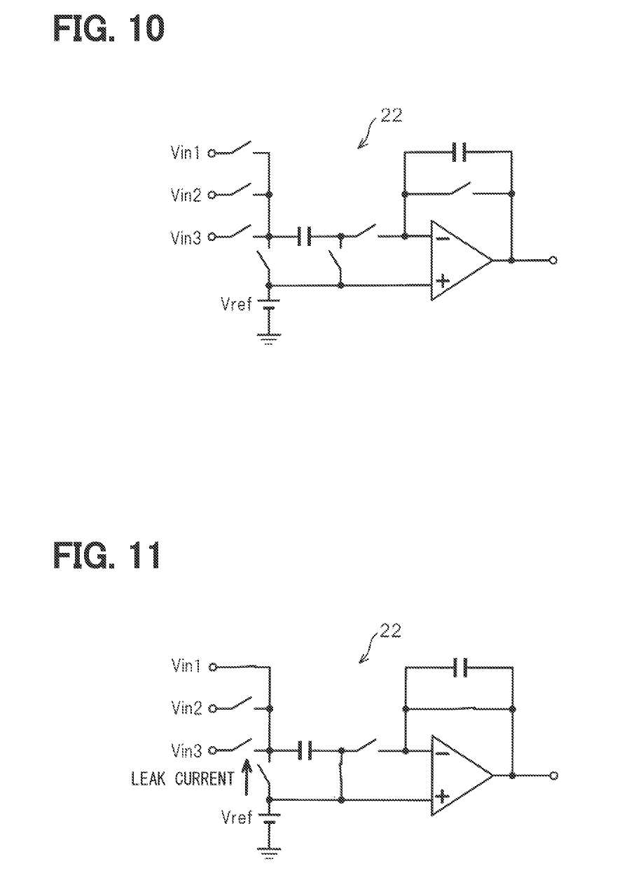

The voltage measuring unit 22 constitutes a sample and hold circuit as shown in FIG. 10, and the input voltages Vin1 to Vin3 are sampled and held when the corresponding input switches are closed. FIG. 11 shows an on state of each switch at the time of sampling and holding the input voltage Vin1, which is the same as the case where the voltage measurement unit 3 of the first embodiment constitutes the sample and hold circuit.

Here, the significance of providing the level shifting resistors R2 (R2_LT, R2_RT and R2_HT) in the third embodiment will be described. When the temperature detected by the thermistor TH rises to a high temperature, the resistance value decreases and the current consumption increases. If the resistance values of the driving resistors R1 (R1_LT, R1_RT, R2_HT) are increased so as to suppress the increase in current consumption, the input voltage Vin approaches the ground level.

A non-inverted input terminal of an operational amplifier constituting the sample and hold circuit is applied with a reference voltage Vref. However, when the input voltage Vin approaches the ground level, the potential difference with the reference voltage Vref increases. As a result, a leak current flows from the non-inverted input terminal toward an inverted input terminal of the operational amplifier. In the third embodiment, since the level shift resistors R2_LT, R2_RT and RT_HT are inserted, the potential difference between the input voltage Vin and the reference voltage Vref at a high temperature can be reduced, and thus the occurrence of the leakage current can be restricted. In general, the switches are provided by MOSFETs or the like. Therefore, by performing the level shift, the threshold can be controlled by means of a substrate bias effect, and thus the leak current can be restricted. The measurement control is performed by a control unit 23.

As described above, according to the third embodiment, the level shifting resistors R2_LT, R2_RT, and R2_HT respectively connected in series to the drive resistors R1_LT, R1_RT, and R1_HT are provided. The voltage measurement unit 22 measures the voltages at the common connection points of the drive resistors R1_LT, R1_RT, and R1_HT and the level shift resistors R2_LT, R2_RT, and R2_HT. In such a configuration, the potentials at the common connection points are level-shifted by the level shifting resistors R2_LT, R2_RT and R2_HT. As a result, the potential differences between the potentials at the common connection points and the reference voltage Vref of the sample and hold circuit is reduced. Therefore, the leak current inside the sample and hold circuit can be reduced, and thus the deterioration of accuracy of the input signal can be suppressed.

### Fourth Embodiment

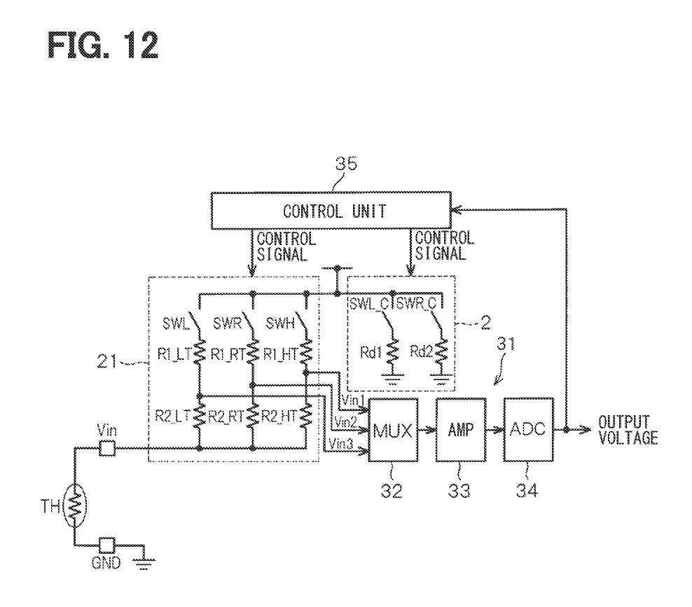

As shown in FIG. 12, in a fourth embodiment, the voltage measurement unit 22 of the third embodiment is replaced with a voltage measurement unit 31, and the voltage measurement unit 31 includes a multiplexer 32, an amplifier 33 and an A/D converter 34. The multiplexer 32 selects each of the voltages Vin3, Vin2, and Vin1 at the respective common connection points according to the switching operations by a control unit 35, and inputs the selected voltage to the amplifier 33 at the next stage. The amplifier 33 amplifies the voltage signal input thereto, and provides the amplified voltage signal to the A/D converter 34. The A/D converter 34 converts an analog voltage input thereto into digital data, and outputs the digital data to an external device and to the control unit 35.

According to the fourth embodiment configured as described above, a leak current similar to that of the third embodiment may occur depending on the potential differences of the input terminals of the multiplexer 32. In such a case, an off leak current may occur when the switch for input selection is in an off state. In the fourth embodiment, since the configuration similar to the third embodiment is employed, the potential difference between the input terminals can be reduced to reduce the off leak current.

### Other Embodiments

It is not always necessary to divide the temperature range into three zones. The temperature range may be divided into two, four, or more zones.

The present disclosure may be applicable to a thermistor having a terminal connected to a power supply.

The present disclosure may be applicable to a thermistor having a positive temperature characteristic.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A thermistor drive circuit comprising:
a plurality of driving resistors configured to be selectively connected to a thermistor, which has a characteristic in which a resistance value changes in accordance with a temperature to be detected, for correcting the characteristic of the thermistor;
at least one current correction resistor configured to be selectively connected between a power supply and a ground;
a voltage measurement unit configured to measure a terminal voltage of the thermistor; and
a controller configured
to switch connection states of the plurality of driving resistors according to the terminal voltage, and
to switch a connection state of the at least one current correction resistor, when switching the connection states of the plurality of driving resistors, to suppress a fluctuation of a power supply current before and after the switching of the connection states of the plurality of driving resistors.

2. The thermistor drive circuit according to claim 1, wherein
the controller is configured to switch the connection state of the at least one current correction resistor so as to reduce a resistance value, when switching the connection sates of the plurality of driving resistors so as to increase a resistance value.

3. The thermistor drive circuit according to claim 1, wherein
the controller is configured to switch the connection state of the at least one current correction resistor stepwise, when switching the connection states of the plurality of driving resistors.

4. The thermistor drive circuit according to claim 1, further comprising:
a plurality of level shifting resistors correspondingly connected in series to the plurality of driving resistors, wherein
the voltage measurement unit is configured to measure a voltage of each of common connection points between the plurality of driving resistors and the plurality of level shift resistors.

5. The thermistor drive circuit according to claim 4, wherein
the voltage measurement unit includes:
a multiplexer having a plurality of input terminals connected to the common connection points;
an amplifier configured to amplify a signal received from the multiplexer; and
an A/D converter configured to convert an analog signal received from the amplifier to a digital signal.
